(19) United States
(12) Patent Application Publication
(10) Pub. No.: US 2023/0369019 A1
(43) Pub. Date: Nov. 16, 2023

(54) PLASMA PROCESSING APPARATUS AND METHOD FOR CONTROLLING SOURCE FREQUENCY OF SOURCE RADIO-FREQUENCY POWER

(71) Applicant: Tokyo Electron Limited, Tokyo (JP)

(72) Inventors: Gen TAMAMUSHI, Miyagi (JP); Chishio KOSHIMIZU, Miyagi (JP); Masahiro INOUE, Miyagi (JP); Shoichiro MATSUYAMA, Miyagi (JP)

(73) Assignee: Tokyo Electron Limited, Tokyo (JP)

(21) Appl. No.: 18/227,370

(22) Filed: Jul. 28, 2023

Related U.S. Application Data
(63) Continuation of application No. PCT/JP2022/002244, filed on Jan. 21, 2022.

(30) Foreign Application Priority Data
Jan. 29, 2021 (JP) 2021-012976
Jan. 29, 2021 (JP) 2021-012983
Feb. 10, 2021 (JP) 2021-019661

(51) Int. Cl. H01J 37/32

(52) U.S. Cl. CPC H01J 37/32137; H01J 37/3299; H01J 37/32183; H01J 2237/327

(57) ABSTRACT

A plasma processing apparatus includes a chamber, a substrate support, a radio-frequency power supply, and a bias power supply controller. The radio-frequency power supply generates source radio-frequency power to generate plasma in the chamber. The bias power supply periodically provides bias energy having a waveform cycle to a bias electrode on the substrate support. The radio-frequency power supply adjusts a source frequency of the source radio-frequency power in an n-th phase period in an m-th waveform cycle of a plurality of waveform cycles based on a change in a degree of reflection of the source radio-frequency power. The change in the degree of reflection is identified with the source frequency being set differently in the n-th phase period in each of two or more waveform cycles preceding the m-th waveform cycle.

### CROSS-REFERENCE TO RELATED APPLICATIONS

The present application is a continuation of International Application No. PCT/JP2022/002244, filed Jan. 21, 2022, which claims priority to Japanese patent application nos. 2021-012976 and 2021-012983, filed Jan. 29, 2021, and Japanese patent application no, 2021-019661, filed Feb. 10, 2021, the entire contents of each of which are incorporated herein by reference.

### FIELD

Exemplary embodiments of the present disclosure relate to a plasma processing apparatus and a method for controlling the source frequency of source radio-frequency (RF) power.

### BACKGROUND

Plasma processing is performed on substrates using a plasma processing apparatus. The plasma processing apparatus uses bias RF power to draw ions in plasma generated in a chamber toward a substrate. Patent Literature 1 below describes a plasma processing apparatus that modulates the power level and the frequency of bias RF power.

### CITATION LIST

### Patent Literature

Patent Literature 1: Japanese Unexamined Patent Application Publication No. 2009-246091

### BRIEF SUMMARY

### Technical Problem

One or more aspects of the present disclosure are directed to a plasma processing apparatus that reduces the degree of reflection of source radio-frequency power.

### Solution to Problem

A plasma processing apparatus according to one exemplary embodiment includes a chamber, a substrate support, a radio-frequency power supply, and a bias power supply. The substrate support is located in the chamber and includes a bias electrode. The radio-frequency power supply generates source radio-frequency power to generate plasma in the chamber. The bias power supply periodically provides bias energy having a waveform cycle to the bias electrode. The radio-frequency power supply sets a source frequency of the source radio-frequency power in each of a plurality of phase periods in each of a plurality of waveform cycles of the bias energy. The radio-frequency power supply performs feedback to adjust the source frequency in an n-th phase period of the plurality of phase periods in an m-th waveform cycle of the plurality of waveform cycles based on a change in a degree of reflection of the source radio-frequency power. The change in the degree of reflection is identified with the source frequency being set differently in the n-th phase period in each of two or more waveform cycles of the plurality of waveform cycles preceding the m-th waveform cycle.

### Advantageous Effects

The plasma processing apparatus according to the above exemplary embodiment reduces the degree of reflection of the source radio-frequency power.

### BRIEF DESCRIPTION OF DRAWINGS

FIG. 1 is a schematic diagram of a plasma processing apparatus according to one exemplary embodiment.

FIG. 2 is a schematic diagram of the plasma processing apparatus according to one exemplary embodiment.

FIG. 3 is an example timing chart of bias energy and the source frequency of source RF power.

FIG. 4 is another example timing chart of bias energy and the source frequency of source RF power.

FIG. 5 is another example timing chart of bias energy.

FIG. 6 is a flowchart of a method for controlling the source frequency of source RF power according to one exemplary embodiment.

FIG. 7 is another example timing chart of bias energy and the source frequency of source RF power,

FIG. 8 is a flowchart of a method for determining the source frequency of source RF power according to one exemplary embodiment.

FIG. 9 is another example timing chart of bias energy and the source frequency of source RF power.

FIG. 10 is another example timing chart of bias energy and the source frequency of source RF power.

FIG. 11 is a graph of an example power spectrum of source RF power.

FIG. 12 is a flowchart of a method for determining the source frequency of source RF power according to another exemplary embodiment.

FIG. 13 is a diagram of an example matcher (or “matching circuitry”),

FIG. 14 is a flowchart of a method for determining the optimal setting according to one exemplary embodiment,

### DETAILED DESCRIPTION

Exemplary embodiments will now be described.

A plasma processing apparatus according to one exemplary embodiment includes a chamber, a substrate support, a radio-frequency power supply, and a bias power supply. The substrate support is located in the chamber and includes a bias electrode. The radio-frequency power supply generates source radio-frequency power to generate plasma in the chamber. The bias power supply periodically provides bias energy having a waveform cycle to the bias electrode. The radio-frequency power supply sets a source frequency of the source radio-frequency power in each of a plurality of phase periods in each of a plurality of waveform cycles of the bias energy. The radio-frequency power supply performs feedback to adjust the source frequency f(m, n) in an n-th phase period of the plurality of phase periods in an m-th waveform cycle of the plurality of waveform cycles based on a change in a degree of reflection of the source radio-frequency power. The symbol f(m, n) refers to the source frequency in the n-th phase period in the m-th waveform cycle. The change in the degree of reflection is identified with the source frequency being set differently in the n-th phase period in each of two or more waveform cycles of the plurality of waveform cycles preceding the m-th waveform cycle.

The source frequency is set differently in the n-th phase period in each of two or more waveform cycles to identify the relationship between a change in the source frequency (frequency shift) and a change in the degree of reflection. Thus, the structure according to the above embodiment can adjust the source frequency in the n-th phase period in the m-th waveform cycle to reduce the degree of reflection of the source radio-frequency power based on a change in the degree of reflection. The structure according to the above embodiment can also reduce the degree of reflection rapidly in each waveform cycle in which the bias energy is provided to the bias electrode on the substrate support.

In one exemplary embodiment, the two or more waveform cycles may include an (m M₁)th waveform cycle and an (m−M₂)th waveform cycle. M₁ and M₂ are natural numbers satisfying M₁>M₂.

In one exemplary embodiment, the feedback may include setting the source frequency f(m−M₂, n) to a frequency resulting from a frequency shift in a first direction being one of a decrease or an increase from the source frequency f(m−n). The frequency shift in the first direction can decrease the degree of reflection. In this case, the feedback may include setting the source frequency f(m, n) to a frequency resulting from the frequency shift in the first direction from the source frequency f(m−M₂, n). In response to the degree of reflection, or the power level, increasing with the source frequency f(m, n) resulting from the frequency shift in the first direction, the feedback may include setting the source frequency f(m+M₃, n) to an intermediate frequency between the source frequencies f(m−M₂, n) and f(m, n). M₃ is a natural number.

In one exemplary embodiment, the degree of reflection can exceed a threshold when the intermediate frequency is set in the n-th phase period in the (m+M₃)th waveform cycle. In this case, the feedback may include setting the source frequency f(m+M₄, n) to a frequency resulting from a frequency shift in a second direction being the other of the decrease or the increase from the intermediate frequency. The amount of the frequency shift in the second direction has a greater absolute value than the amount of the frequency shift in the first direction. M₄ is a natural number satisfying M₄>M₃.

In one exemplary embodiment, the amount of the frequency shift in the first direction may have a greater absolute value for setting the source frequency f(m, n) than for setting the source frequency f(m−M₂, n),

In one exemplary embodiment, the feedback may include setting the source frequency f(m−M₂, n) to a frequency resulting from a frequency shift in a first direction being one of a decrease or an increase from the source frequency f(m−M₁, n). The frequency shift in the first direction can increase the degree of reflection. In this case, the feedback may include setting the source frequency f(m, n) to a frequency resulting from a frequency shift in a second direction being the other of the decrease or the increase from the source frequency f(m−M₂, n).

In one exemplary embodiment, the bias energy may be bias radio-frequency power having a bias frequency being the inverse of the time length of the waveform cycle. In some embodiments, the bias energy may include a pulse of a voltage provided to the bias electrode in each of the plurality of waveform cycles having a time length being the inverse of the bias frequency.

In one exemplary embodiment, the radio-frequency power supply may set, in a plurality of phase periods in the first waveform cycle of the plurality of waveform cycles, a plurality of frequencies included in a predefined initial frequency group.

In one exemplary embodiment, the plasma processing apparatus may further include a controller.

In one exemplary embodiment, the controller may set a plurality of frequencies different from each other as source frequencies in identical phase periods in a plurality of reference cycles each being the waveform cycle. The controller may select, from the plurality of frequencies, a specific frequency minimizing the degree of reflection in each of the plurality of phase periods to determine a plurality of specific frequencies for the respective plurality of phase periods. The controller may store the plurality of specific frequencies into a storage in the plasma processing apparatus as the plurality of frequencies in the initial frequency group.

In one exemplary embodiment, the controller may cause the radio-frequency power supply to generate source radio-frequency power having a plurality of frequency components to generate plasma in the chamber in a reference cycle being the waveform cycle. The controller may determine a lowest ratio of a plurality of ratios of power levels of reflected waves of the plurality of frequency components to power levels of traveling waves of the plurality of frequency components in each of a plurality of phase periods in the reference cycle. The controller may identify a frequency of a frequency component of the plurality of frequency components corresponding to the lowest ratio in each of the plurality of phase periods to determine a plurality of specific frequencies for the respective plurality of phase periods. The controller may store the plurality of specific frequencies into a storage in the plasma processing apparatus as the plurality of frequencies in the initial frequency group,

In one exemplary embodiment, the plasma processing apparatus may further include a matcher. The matcher includes a first variable capacitor and a second variable capacitor. The first variable capacitor is coupled between a ground and a node on a teed line coupling the radio-frequency power supply and a radio-frequency electrode to receive the source radio-frequency power. The second variable capacitor is coupled between the node and the radio-frequency electrode. In a first waveform cycle of the plurality of waveform cycles, the matcher may use, selectively from a plurality of predefined optimal matcher settings for the first variable capacitor and for the second variable capacitor, an optimal matcher setting corresponding to a process to be performed in the plasma processing apparatus. In the plurality of phase periods in the first waveform cycle, the radio-frequency power supply may set, selectively from a plurality of predefined initial frequency groups, a plurality of frequencies included in the initial frequency group corresponding to the process to be performed in the plasma processing apparatus.

In one exemplary embodiment, the controller may generate a plurality of provisional settings while sequentially switching a matcher setting for the first variable capacitor and for the second variable capacitor among a plurality of matcher settings under a condition for the process. To generate the plurality of provisional settings, the controller may set, with each of the plurality of matcher settings, a plurality of frequencies different from each other as source frequencies in identical phase periods in the plurality of reference cycles each being the waveform cycle. The controller may select, from the plurality of frequencies, a provisional frequency minimizing the degree of reflection in each of the plurality of phase periods. The controller may thus generate a plurality of provisional settings each including a provisional frequency group and including a corresponding matcher setting of the plurality of matcher settings. The provisional frequency group may include a plurality of provisional frequencies for the respective plurality of phase periods. The controller may identify, from the plurality of provisional settings, a provisional setting minimizing the degree of reflection. The controller may store, into the storage in the plasma processing apparatus, the matcher setting and the provisional frequency group included in the identified provisional setting as the optimal matcher setting and the initial frequency group corresponding to the above process.

In one exemplary embodiment, the controller may generate a plurality of provisional settings while sequentially switching a matcher setting for the first variable capacitor and for the second variable capacitor among a plurality of matcher settings under a condition for the process. To generate the plurality of provisional settings, the controller may (a) cause the radio-frequency power supply to generate, with each of the plurality of matcher settings, source radio-frequency power having a plurality of frequency components to generate plasma in the chamber in a reference cycle being the waveform cycle, (h) determine a lowest ratio of a plurality of ratios of power levels of reflected waves of the plurality of frequency components to power levels of traveling waves of the plurality of frequency components in each of a plurality of phase periods in the reference cycle, and (c) identify a frequency of a frequency component of the plurality of frequency components corresponding to the lowest ratio in each of the plurality of phase periods to determine a plurality of provisional frequencies for the respective plurality of phase periods. The controller may thus generate a plurality of provisional settings each including a provisional frequency group and including a corresponding matcher setting of the plurality of matcher settings. The provisional frequency group may include a plurality of provisional frequencies for the respective plurality of phase periods. The controller may identify, from the plurality of provisional settings, a provisional setting minimizing the degree of reflection. The controller may store, into the storage in the plasma processing apparatus, the matcher setting and the provisional frequency group included in the identified provisional setting as the optimal matcher setting, and the initial frequency group corresponding to the above process.

A method according to another exemplary embodiment is a method for controlling a source frequency of source radio-frequency power. The method includes (a) providing bias energy to a bias electrode on a substrate support located in a chamber in a plasma processing apparatus. The bias energy has a waveform cycle and is periodically provided to the bias electrode. The method further includes (b) providing source radio-frequency power from a radio-frequency power supply to generate plasma in the chamber. The method further includes (c) setting a source frequency of the source radio-frequency power in each of a plurality of phase periods in each of a plurality of waveform cycles. The source frequency f(m, n) is adjusted based on a change in the degree of reflection of the source radio-frequency power. The change in the degree of reflection is identified with the source frequency being set differently in the n-th phase period in each of two or more waveform cycles preceding the m-th waveform cycle.

Exemplary embodiments will now be described in detail with reference to the drawings. In the figures, the same or corresponding components are given the same reference numerals.

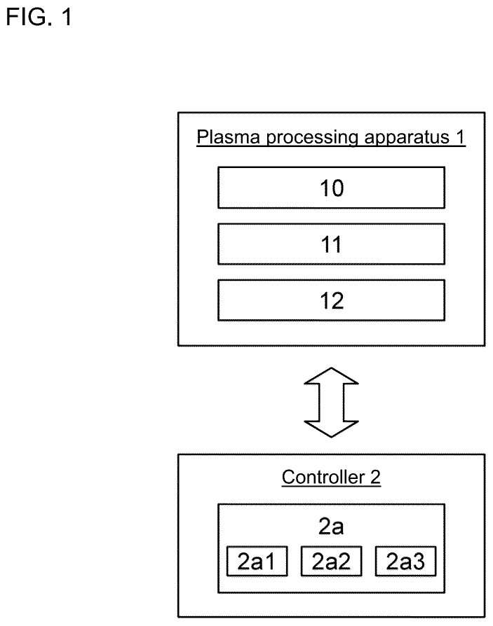

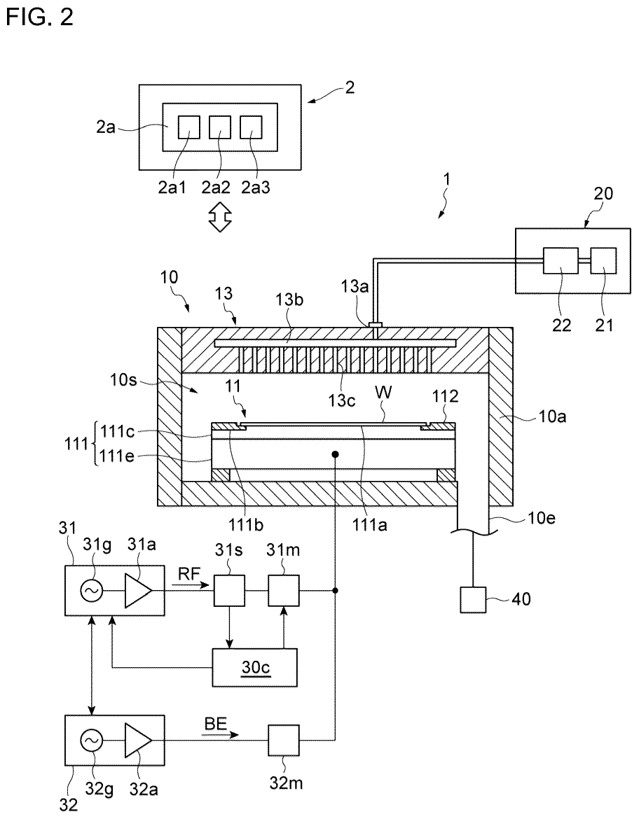

FIGS. 1 and 2 are each a schematic diagram of a plasma processing, apparatus according to one exemplary embodiment.

In one embodiment, a plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet connects to a gas supply unit 20 (described later). The gas outlet connects to an exhaust system (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (MVP), or surface wave plasma (SWP). Various plasma generators including an alternating current (AC) plasma generator and a direct current (DC) plasma generator may be used,

The controller 2 processes computer-executable instructions that cause the plasma processing apparatus 1 to perform various steps described in one or more embodiments of the present disclosure. The controller 2 may control the components of the plasma processing apparatus 1 to perform various steps described herein. In one embodiment, some or all of the components of the controller 2 may be included in the plasma processing apparatus 1, The controller 2 may include, for example, a computer 2a. The computer 2a may include, for example, a central processing unit (CPU) 2a1, a storage 2a2, and a communication interface 2a3. The CPU 2a1 may perform various control operations based on programs stored in the storage 2a2. The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 with a communication line such as a local area network (LAN).

An example structure of a capacitively coupled plasma processing apparatus as an example of the plasma processing apparatus 1 will now be described. The capacitively coupled plasma processing apparatus 1 includes a plasma processing chamber 10, a gas supply unit 20, a power supply 30, and an exhaust system 40. The plasma processing apparatus 1 also includes a substrate support 11 and a gas inlet unit. The gas inlet unit allows at least one process gas to be introduced into the plasma processing chamber 10. The gas inlet unit includes a shower head 13, The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower lead 13, a side wall 10a of the plasma processing chamber 10, and the substrate support 11. The side wall 10a is grounded. The shower head 13 and the substrate support 11 are electrically insulated from a housing of the plasma processing chamber 10.

The substrate support 11 includes a body 111 and a ring assembly 112. The body 111 includes a central area (substrate support surface) 111a for supporting a substrate (wafer) W and an annular area (ring support surface) 111b for supporting the ring assembly 112. The annular area 111b of the body 111 surrounds the central area 111a of the body 111 as viewed in plan. The substrate W is located on the central area 111a of the body 111. The ring assembly 112 is located on the annular area 111b of the body 111 to surround the substrate W on the central area 111a of the body 111. In one embodiment, the body ill includes a base 111e and an electrostatic chuck (ESC) 111c, The base 111e includes a conductive member. The conductive member in the base 111e may serve as a lower electrode. The ESC 111c is located on the base 111e. The upper surface of the ESC 111c includes the substrate support surface 111a, The ring assembly 112 includes one or more annular members. At least one of the annular members is an edge ring. Although not shown in the figures, the substrate support 11 may also include a temperature control module that adjusts at least one of the ESC 111c, the ring assembly 112, or the substrate W to a target temperature. The temperature control module may include a heater, a heat-transfer medium, a channel, or a combination of these. The channel allows a heat-transfer fluid such as brine or gas to flow. The substrate support 11 may include a heat-transfer gas supply unit to supply a heat-transfer gas into a space between the back surface of the substrate W and the substrate support surface 111a.

The shower head 13 introduces at least one process gas from the gas supply unit 20 into the plasma processing space 10s. The shower head 13 has at least one gas inlet 13a, at least one gas-diffusion compartment 13b, and multiple gas inlet ports 13c. The process gas supplied to the gas inlet 13a passes through the gas-diffusion compartment 13b and is introduced into the plasma processing space 10s through the multiple gas inlet ports 13c, The shower head 13 also includes a conductive member. The conductive member in the shower head 13 may serve as an upper electrode. In addition to the shower head 13, the gas inlet unit may include one or more side gas injectors (SGIs) that are installed in one or more openings in the side wall 10a,

The gas supply unit 20 may include at least one gas source 21 and at least one flow controller 22. In one embodiment, the gas supply unit 20 allows supply of at least one process gas from each gas source 21 to the shower head 13 through the corresponding flow controller 22. The flow controller 22 may include, for example, a mass flow controller or a pressure-based flow controller. The gas supply unit 20 may further include one or more flow rate modulators that supply one or more process gases at a modulated flow rate or in a pulsed manner.

The exhaust system 40 may be, for example, connected to a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

The plasma processing apparatus 1 further includes a radio-frequency (RF) power supply 31 and a bias power supply 32. The plasma processing apparatus 1 may further include a sensor 31s and a controller 30c.

The RF power supply 31 generates source radio-frequency power RF to generate plasma in the chamber (plasma processing chamber 10). The source radio-frequency power RF has a source frequency of, for example, 13 to 150 MHz inclusive. In one embodiment, the RF power supply 31 may include an RF signal generator 31g and an amplifier 31a. The RF signal generator 312 generates an RF signal. The amplifier 31a amplifies the RF signal input from the RF signal generator 31g to generate the source radio-frequency power RF, and outputs the source radio-frequency power RF. The RF signal generator 31g may include a programmable processor or a programmable logic device such as a field-programmable gate array (FPGA). A digital-to-analog (D/A) converter may be coupled between the RF signal generator 31g and the amplifier 31a.

The RF power supply 31 is coupled to an RF electrode with a matcher 31m in between. In one embodiment, the RF electrode may be included in the base 111e. In another embodiment, the RF electrode may be included in the ESC 111c. The RF electrode may also serve as a bias electrode (described later). In some embodiments, the RF electrode may be the upper electrode. The matcher 31m includes a matching circuit. The matching circuit in the matcher 31m has a variable impedance. The matching circuit in the matcher 31m is controlled by the controller 30c. The impedance of the matching circuit in the matcher 31m is adjusted to match the impedance of a load coupled to the RF power supply 31 with the output impedance of the RF power supply 31.

The sensor 31s outputs, to the controller 30c, a reflected wave of the source radio-frequency power RF returning from the load coupled to the RF power supply 31. The sensor 31s may be coupled between the RF power supply 31 and the matcher 31m. The sensor 31s may be coupled between the matcher 31m and the RF electrode. For example, the sensor 31s may be coupled between the bias electrode and the junction of an electric path extending from the matcher 31m to the bias electrode and an electric path extending from a matcher 32m (described later) to the bias electrode. In some embodiments, the sensor 31s may be coupled between the junction and the matcher 31m. The sensor 31s includes, for example, a directional coupler. The directional coupler outputs the reflected wave returning from the load coupled to the RF power supply 31. The reflected wave output from the directional coupler is converted to a digital signal by analog-to-digital (AD) conversion. The digital reflected wave is used in the controller 30c. The sensor 31s may be separate from the matcher 31m, or may be a part of the matcher 31m.

The bias power supply 32 is electrically coupled to the bias electrode. In one embodiment, the bias electrode is included in the base 111e. In another embodiment, the bias electrode may be included in the ESC 111c. The bias power supply 32 periodically provides bias energy BE having a waveform cycle CY to the bias electrode. More specifically, the bias energy BE is provided to the bias electrode in each of multiple waveform cycles CY. In one embodiment, each of the multiple waveform cycles CY is the waveform cycle of the bias energy BE provided to the bias electrode in a process period in which the substrate W is subjected to a process in the plasma processing apparatus 1. Each of the multiple waveform cycles CY is defined by the bias frequency that may be, for example, 50 kHz to 27 MHz inclusive. Each of the multiple waveform cycles CY has a time length being the inverse of the bias frequency.

The multiple waveform cycles CY occur in time sequence. A waveform cycle CY(m) herein refers to the m-th waveform cycle of the multiple waveform cycles CY. In other words, a waveform cycle CY(m) refers to any waveform cycle of the multiple waveform cycles CY.

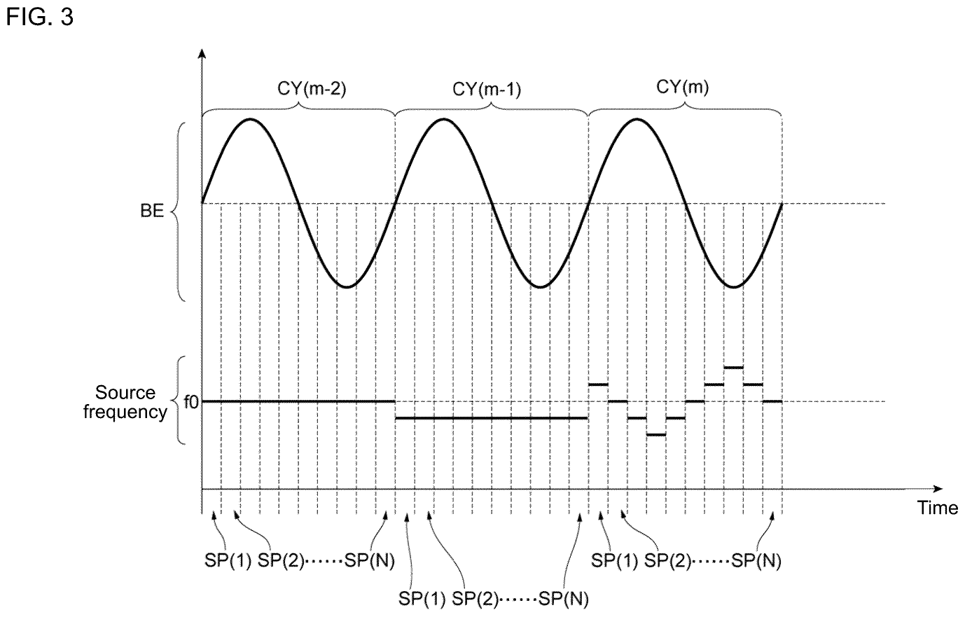

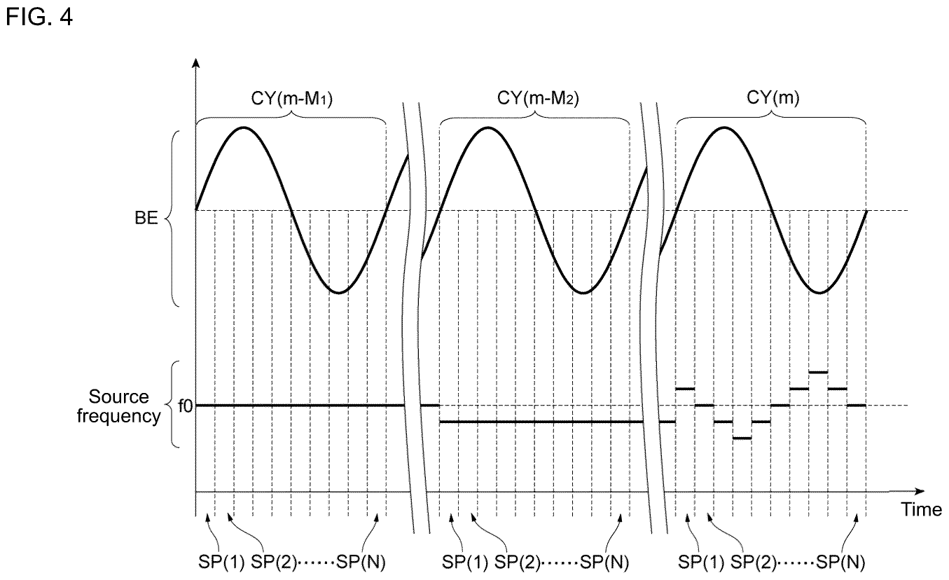

FIGS. 3 and 4 will now be referred to FIG. 3 is an example timing chart of bias energy and the source frequency of source RF power. FIG. 4 is another example timing chart of bias energy and the source frequency of source RF power. In one embodiment, as shown in FIGS. 3 and 4, the bias energy BE may be bias RF power having a bias frequency. In this case, as show r in FIG. 2, the bias power supply 32 may include an RF signal generator 32g and an amplifier 32a. The RF signal generator 32g generates an RF signal. The amplifier 32a amplifies the RF signal input from the RF signal generator 32g to generate bias RF power, and provides the generated bias RF power to the bias electrode as the bias energy BE. The RF signal generator 32g may include a programmable processor or a programmable logic device such as an FPGA, A D/A converter may be coupled between the RF signal generator 32g and the amplifier 32a.

For the bias energy BE being bias RF power, the bias power supply 32 is coupled to the bias electrode with the matcher 32m in between. The matcher 32m includes a matching circuit having a variable impedance and controlled by the controller 30c, The impedance of the matching circuit in the matcher 32m is adjusted to match the impedance of a load coupled to the bias power supply 32 with the output impedance of the bias power supply 32.

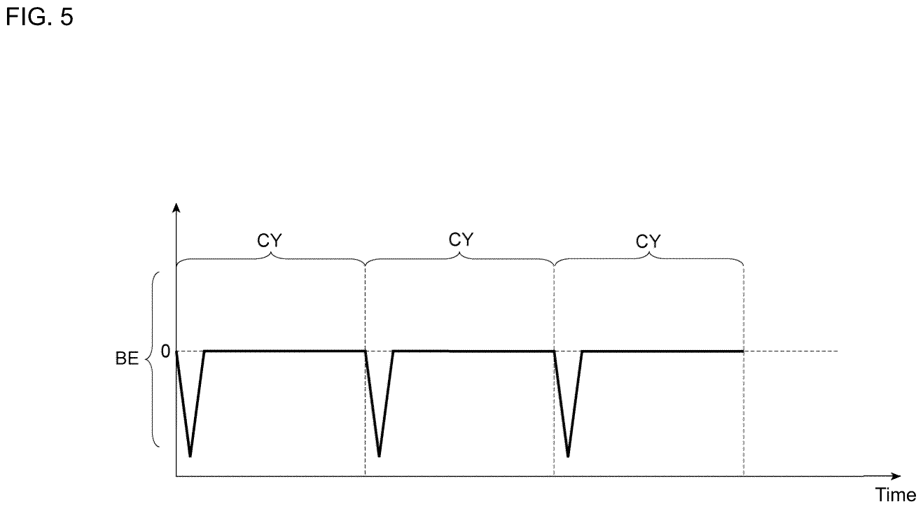

FIG. 5 is another example timing chart of bias energy. In another embodiment, as shown in FIG. 5, the bias energy BE may include a pulse of a voltage provided to the bias electrode in each of the multiple waveform cycles CY. The pulse of the voltage as the bias energy BE may be a pulse of a negative voltage as in the example of FIG. 5, or may be a pulse of any other voltage. The pulse of the voltage as the bias energy BE may have a triangular or square waveform, or any other waveform. For the bias energy BE being the pulse of the voltage, the matcher 32m shown in FIG. 2 may be replaced with a filter coupled between the bias power supply 32 and the bias electrode to block the source radio-frequency power RF.

The bias power supply 32 is synchronized with the RF power supply 31 using a synchronization signal that may be provided from the bias power supply 32 to the RF power supply 31. In some embodiments, the synchronization signal may be provided from the RE power supply 31 to the bias power supply 32, in some embodiments, the synchronization signal may be provided from another device, such as the controller 30c, to the RE power supply 31 and to the bias power supply 32.

The controller 30c controls the RE power supply 31. The controller 30c may include a processor such as a CPU. The controller 30c may be a part of the matcher 31m or a part of the RE power supply 31, or may be separate from the matcher 31m and from the RF power supply 31. In some embodiments, the controller 2 may also serve as the controller 30c.

The controller 30c sets the source frequency of the source radio-frequency power RE in each of multiple phase periods SP in each of the multiple waveform cycles CY. In the examples of FIGS. 3 and 4, each of the multiple waveform cycles CY includes N phase periods SP(i) to SP(N), where N is an integer greater than or equal to 2. The phase periods SP(i) to SP(N) are N phase periods into which each of the multiple waveform cycles CY are divided. The multiple phase periods SP in each of the multiple waveform cycles CY have the time lengths that may be the same as or different from one another. A phase period SP(n) herein refers to the n-th phase period of the phase periods SP(1) to SP(N). In other words, a phase period SP(n) refers to any phase period in each of the multiple waveform cycles CY. A phase period SP(m, n) refers to the n-th phase period in the waveform cycle CY(m). In the embodiment described below, the source frequency is set by the controller 30c. For the controller 30c being a part of the RE power supply 31, however, the source frequency may be set by the RE power supply 31.

The controller 30c performs feedback described below for setting the source frequency. In the feedback, the controller 30c adjusts the source frequency of the source radio-frequency power RF in the phase period SP(m, n) based on a change in the degree of reflection of the source radio-frequency power RE. The degree of reflection of the source radio-frequency power RE is indicated by, for example, a power level Pr of the reflected wave of the source radio-frequency power RE output from the sensor 31s, The change in the degree of reflection is identified with the source frequency being set differently in the corresponding phase period SP(n) in each of two or more waveform cycles CY preceding the waveform cycle CY(m).

The source frequency is set differently in the phase period SP(n) in each of two or more waveform cycles CY to identify the relationship between a change in the source frequency (frequency shift) and a change in the degree of reflection of the source RF power. Thus, the plasma processing apparatus 1 can adjust the source frequency in the phase period SP(m, n) to reduce the degree of reflection based on a change in the degree of reflection. The plasma processing apparatus 1 can also reduce the degree of reflection rapidly in each of the multiple waveform cycles CY in which the bias energy BE is provided to the bias electrode on the substrate support 11.

In one embodiment, the two or more waveform cycles CY preceding the waveform cycle CY(in) include a waveform cycle CY(m−M₁) and a waveform cycle CY(m−M₂), where M₁ and M₂ are natural numbers satisfying M₁>M₂,

In one embodiment, the waveform cycle CY(m−M₁) is the waveform cycle CY(m−2Q), and the waveform cycle CY(m−M₂) is the waveform cycle CY(m− Q). In the example of FIGS. 3, Q and M₂ are both 1, and 2Q and M₁ are both 2, Q may be an integer greater than or equal to 2.

In the feedback, the controller 30c sots the source frequency f(m−M₂, n) to a frequency resulting from a frequency shift in a first direction from the source frequency f(m−M₁, n). The symbol f(m, n) indicates the source frequency of the source radio-frequency power RF in the phase period SP(m, n), and, is expressed as f(m, n)=f(m−M₂, n) Δ(m, n), where Δ(m, n) is a frequency shift amount. The frequency shift in the first direction is either a decrease or an increase in frequency. For the frequency shift in the first direction being a decrease in frequency, Δ(m, n) has a negative value. For the frequency shift in the first direction being an increase in frequency, Δ(m, n) has a positive value.

In FIGS. 3 and 4, the multiple phase periods SP in the waveform cycle CY(m−M₁) have the same source frequency, or specifically, f0, but may have different source frequencies. In FIGS. 3 and 4, the multiple phase periods SP in the waveform cycle CY(m−M₂) have the same source frequency, or specifically, a frequency decreased from f0, but may have a frequency increased from f0.

In the feedback, when the degree of reflection decreases with the source frequency f(m−M₂, n) resulting from the frequency shift in the first direction, the controller 30c sets the source frequency n) to a frequency resulting from the frequency shift in the first direction from the source frequency f(m−M₂, n). For example, when the power level Pr(m−n) decreases from the power level Pr(m−M₁, n) in response to the frequency shift in the first direction, the controller 30c sets the source frequency f(m, n) to a frequency resulting from the frequency shift in the first direction from the source frequency f(m−M₂, n). The symbol Pr(m, n) indicates the power level Pr of the reflected wave of the source radio-frequency power RF in the phase period SP(m, n).

In one embodiment, the frequency shift amount Δ(m, n) in the first direction in the phase period SP(m, n) may be the same as the frequency shift amount Δ(m−M₂, n) in the first direction in the phase period SP(m−M₂, n), More specifically, the frequency shift amount Δ(m, n) may have the same absolute value as the frequency shift amount Δ(m−M₂, n). In some embodiments, the frequency shift amount Δ(m, n) may have a greater absolute value than the frequency shift amount Δ(m−M₂, n), In some embodiments, the frequency shift amount Δ(m, n) may have a greater absolute value for a greater degree of reflection (e.g., for a greater power level Pr(m− Q, n) of the reflected wave) in the phase period SP(m−M₂, n). For example, the frequency shift amount Δ(m, n) may have the absolute value determined by a function of the degree of reflection (e.g., the power level Pr(m− Q, n) of the reflected wave).

In the feedback, the source frequency f(m−M₂, n) resulting from the frequency shift in the first direction can increase the degree of reflection. For example, the power level Pr(m−M₂, n) of the reflected wave can increase from the power level Pr(m−M₁, n) of the reflected wave in response to the frequency shift in the first direction. In this case, the controller 30c may set the source frequency f(m, n) to a frequency resulting from a frequency shift in a second direction from the source frequency f(m−M₂, n). The source frequency in the phase period

SP(n) in each of two or more waveform cycles preceding the waveform cycle CY(m) may be updated to be a frequency resulting from the frequency shift in the first direction from the source frequency in the phase period SP(n) in its corresponding preceding waveform cycle. In this case, for an upward trend of the degree of reflection e.g., the power level Pr of the reflected wave) in the phase period SP(n) in each of the two or more waveform cycles, or their average, the source frequency in the phase period SP(n) in the waveform cycle CY(m) may be set to a frequency resulting from the frequency shift in the second direction. For example, the source frequency in the phase period SP(n) in the waveform cycle CY(m) may be set to a frequency resulting from the frequency shift in the second direction from the source frequency in the earliest of the two or more waveform cycles.

In the feedback, the source frequency f(m, n) resulting from the frequency shift in the first direction can increase the degree of reflection. For example, the power level Pr(m, n) of the reflected wave can increase from the power level Pr(m−M₂, n) of the reflected wave in response to the frequency shift in the first direction. In this case, the controller 30c may set the source frequency in the phase period SP(n) in the waveform cycle CY(m+M₃) to an intermediate frequency. The waveform cycle CY(m+M₃) is subsequent to the waveform cycle CY(m), where M₃ is a natural number that may satisfy M₃=M₂. The intermediate frequency that may be set in the phase period SP(m+M₃, n) is between the source frequencies f(m M₂, n) and f(m, n), and may be the average of the source frequencies f(m−M₂, n) and f(m, n).

In the feedback, the degree of reflection (e.g., the power level Pr) can exceed a predetermined threshold when the intermediate frequency is set in the phase period SP(m+M₃, n). In this case, the controller 30c may set the source frequency in the phase period SP(n) in the waveform cycle CY(m f M₄) to a frequency resulting from the frequency shift in the second direction from the intermediate frequency. The waveform cycle CY(m+M₄) is subsequent to the waveform cycle CY(m+M₃), where M₄ is a natural number that may satisfy M₄=M₁. The threshold is predetermined. The frequency shift amount Δ(m+M₄, n) in the second direction has a greater absolute value than the frequency shift amount Δ(m, n) in the first direction. This avoids the situation in which the degree of reflection (e.g., the power level Pr of the reflected wave) fails to decrease from a local minimum value. The thresholds for the multiple phase periods SP in each of the multiple waveform cycles CY may be the same as or different from one another.

The plasma processing apparatus 1 may use, as the degree of reflection in each phase period, a representative value of measurement values in the phase period. The representative value may be the average or the maximum of measurement values in each phase period. The plasma processing apparatus 1 may use, as the measurement value, at least one of the power level Pr of the reflected wave described above, the ratio of the power level Pr of the reflected wave to the output power level of the source radio-frequency power RF (hereafter, a reflectance), a phase difference θ between a voltage V and an current 1, or an impedance Z of the load coupled to the RF power supply 31.

The plasma processing apparatus 1 may include a voltage-current (VI) sensor in addition to or in place of the above sensor 31s. The VI sensor measures the voltage V and the current 1 on the feed line for the source radio-frequency power RF between the RF power supply 31 and the RF electrode. The VI sensor may be coupled between the RF power supply 31 and the matcher 31m, The VI sensor may be coupled between the matcher 31m and the RF electrode. For example, the VI sensor may be coupled between the bias electrode and the junction of an electric path extending from the matcher 31m to the bias electrode and an electric path extending from the matcher 32m to the bias electrode. In some embodiments, the VI sensor may be coupled between the junction and the matcher 31.tn. The VI sensor may be a part of the matcher 31m.

The source frequency for each of the multiple phase periods SP in each waveform cycle CY may be changed based on the voltage V, the current 1, and the phase difference θ between the voltage V and the current 1 to cause the impedance of the load coupled to the RF power supply 31 to be closer to the matching point. The variable impedance of the matcher 31m may be adjusted based on the voltage V, the current 1, and the phase difference θ to cause the impedance of the load coupled to the RF power supply 31 to be closer to the matching point. When the feed line for the source radio-frequency power RF has a characteristic impedance of 50Ω, the matching point has a real resistive component of 50Ω, and the phase difference θ is 0°.

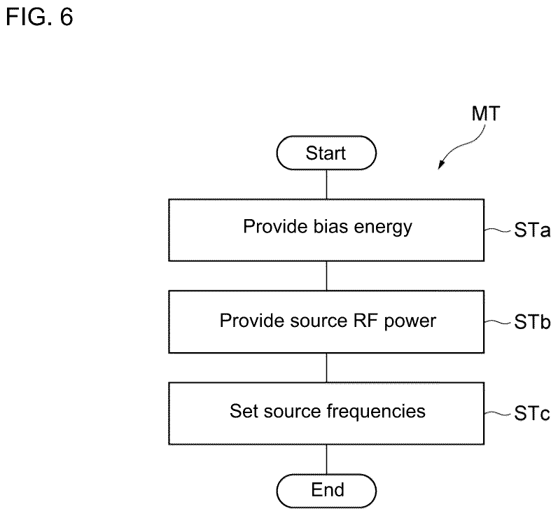

A method for controlling the source frequency of source RF power according to one exemplary embodiment will now be described with reference to FIG. 6. FIG. 6 is a flowchart of a method for controlling the source frequency of source RF power according to one exemplary embodiment. A method MT in FIG. 6 starts from step STa or step STb.

In step STa, the bias energy BE is provided to the bias electrode, Step STb is performed in parallel with step STa. In step STb, the source radio-frequency power RF is provided from an RF power supply (e.g., the RF power supply 31) to generate plasma in the chamber.

In step STc, the source frequency of the source radio-frequency power RF is set for each of the multiple phase periods SP in each of the multiple waveform cycles CY. More specifically, in step STc, the source frequency f(m, n) of the source radio-frequency power RF in the phase period SP(m, n) in the waveform cycle CY(m) is adjusted based on a change in the degree of reflection (e.g., the power level Pr of the reflected wave) of the source radio-frequency power RF. The change in the degree of reflection (e.g., the power level Pr of the reflected wave) is identified with the source frequency being set differently in the corresponding phase period SP(n) in each of two or more waveform cycles CY preceding the waveform cycle CY(m). The source frequencies are adjusted for the multiple phase periods SP in each of the multiple waveform cycles CY by the controller 30c in the manner described above.

In the plasma processing apparatus 1, the RF power supply 31 may set multiple frequencies included in a predefined initial frequency group. The multiple frequencies included in the initial frequency group are set in the respective multiple phase periods SP in the first waveform cycle CY(1) of the multiple waveform cycles CY

The determination of the initial frequency group in some embodiments will now be described.

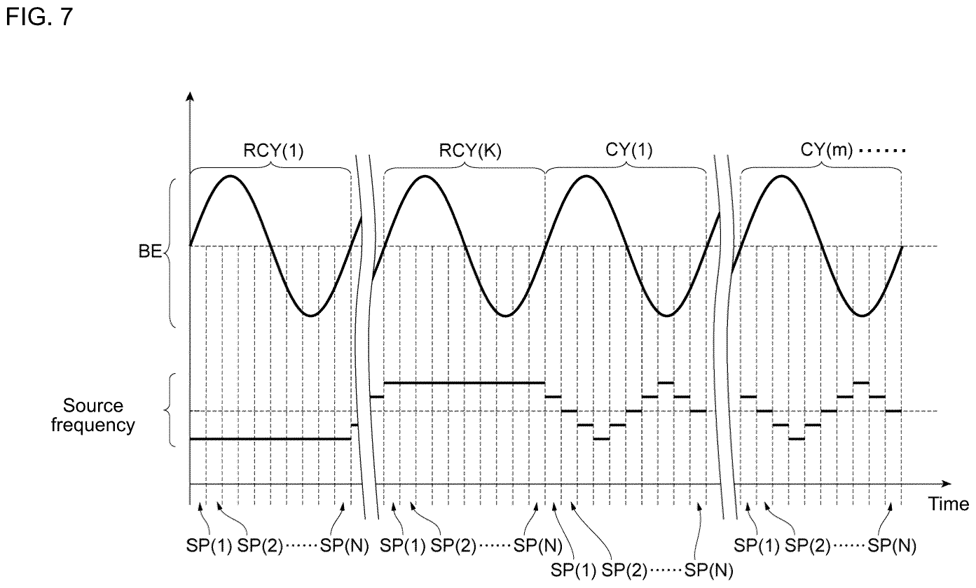

FIG. 7 will now be referred to FIG. 7 is another example timing chart of bias energy and the source frequency of source RF power. In one embodiment, the controller 30c controls the bias power supply 32 to provide the bias energy BE to the bias electrode in each of multiple reference cycles RCY of the bias energy BE. Each of the multiple reference cycles RCY is defined by the above bias frequency and has the same time length as each of the multiple waveform cycles CY. In other words, each of the multiple reference cycles RCY is the waveform cycle of the bias energy BE and has a time length being the inverse of the bias frequency. In the example of FIG. 7, K reference cycles RCY, or reference cycles RCY(1) to RCY(K), are defined. The multiple reference cycles RCY occur in time sequence before the multiple waveform cycles CY As described above, in one embodiment, each of the multiple waveform cycles CY is the waveform cycle of the bias energy BE provided to the bias electrode in the process period in which the substrate W is subjected to a process in the plasma processing apparatus 1. Each of the multiple reference cycles RCY is the waveform cycle of the bias energy BE provided to the bias electrode in a preliminary period before the process period to determine the initial frequency group. In the preliminary period, the initial frequency group may be determined under the condition for the process to be performed in the process period.

The controller 30c controls the RF power supply 31 to generate the source radio-frequency power RF to generate plasma in the chamber in each of the multiple reference cycles

RCY. In the multiple waveform cycles CY the substrate W may be placed on the substrate support 11 while plasma is being generated, in the multiple reference cycles RCY, the substrate W may or may not be placed on the substrate support 11.

As shown in FIG. 7, the multiple reference cycles RCY and the multiple waveform cycles CY each include the multiple phase periods SP. In other words, the multiple reference cycles RCY and the multiple waveform cycles CY are each divided into N phase periods SP(1) to SP(N), where N is an integer greater than or equal to 2. The multiple phase periods SP in each of the multiple reference cycles RCY and in each of the multiple waveform cycles CY have the time lengths that may be the same as or different from one another. A phase period SP(n) herein refers to the n-th phase period of the phase periods SKI) to SP(N) in each of the multiple reference cycles RCY and in each of the multiple waveform cycles CY.

The controller 30c controls the RF power supply 31 to set multiple frequencies different from each other as the source frequencies in the identical phase periods SP(n) in the multiple reference cycles RCY. The controller 30c selects, from the multiple frequencies, a specific frequency minimizing the degree of reflection (e.g., the power level Pr of the reflected wave) of the source radio-frequency power RF in each of the multiple phase periods SP to determine multiple specific frequencies of the source RF power for the respective multiple phase periods SP. In the example of FIG. 7 the reference cycles RCY(1) to RCY(K) have predetermined source frequencies of the source radio-frequency power RF that are different from each other. The degree of reflection (e.g., the power level Pr) in each of the phase periods SP(1) to SP(N) in each of the reference cycles RCY(1) to RCY(K) is then determined. Based on the resulting degrees of reflection, the specific frequency of the source radio-frequency power RF minimizing the degree of reflection is selected for each of the phase periods SP(1) to SP(N). The multiple specific frequencies for the respective phase periods SP(1) to SP(N) are stored into the storage in the plasma processing apparatus 1 as the multiple frequencies in the initial frequency group.

The plasma processing apparatus 1 determines the multiple specific frequencies of the source radio-frequency power RF to reduce the degrees of reflection in the multiple phase periods SP. The plasma processing apparatus 1 can thus reduce the degree of reflection of the source RF power in each of the multiple waveform cycles CY in which the bias energy BE is provided to the bias electrode.

In one embodiment, the controller 30c may control the RF power supply 31 to set the multiple frequencies in the initial frequency group, or in other words, the above multiple specific frequencies, as the source frequencies for the respective multiple phase periods SP in at least one of the multiple waveform cycles CY subsequent to the multiple reference cycles RCY. In other words, in the phase period SP(n) in at least one of the multiple waveform cycles CY, the controller 30c may control the RF power supply 31 to set the specific frequency for the phase period SP(n), selectively from the multiple specific frequencies. The multiple specific frequencies may be used as source frequencies for the respective multiple phase periods SP in every waveform cycle CY.

The multiple specific frequencies, or in other words, the multiple frequencies in the initial frequency group, may be set in the respective multiple phase periods SP in the first waveform cycle CY(1) of the multiple waveform cycles CY: In the multiple waveform cycles CY, the feedback described above may be performed.

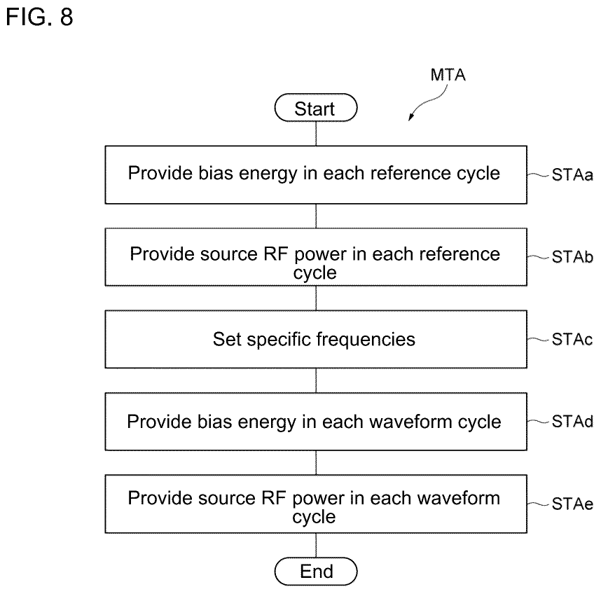

A method for determining the source frequency of source RF power according to one exemplary embodiment will now be described with reference to FIG. 8. FIG. 8 is a flowchart of a method for determining the source frequency of source RF power according to one exemplary embodiment. A method NITA in FIG. 8 starts from step STAa or step STAb.

In step STAa, the bias energy BE is provided to the bias electrode in each of the multiple reference cycles RCY, Step STAb is performed in parallel with step STAa. In step STAb, the source radio-frequency power RF is provided from an RF power supply (e.g., the RF power supply 31) to generate plasma in the chamber in each of the multiple reference cycles RCY. In step STAb, multiple frequencies different from each other are set as the source frequencies in the identical phase periods SP(n) in the multiple reference cycles RCY.

In step STAc, multiple specific frequencies of the source radio-frequency power RF are determined for the respective multiple phase periods SP. More specifically, in step STAc, the specific frequency minimizing the degree of reflection of the source radio-frequency power RF (e.g., the power level of the reflected wave) is selected from the source frequencies in the identical phase periods SP(n) in the multiple reference cycles RCY.

The method MT may further include steps STAd and STAe. In step STAd bias energy is provided to the bias electrode in each of the multiple waveform cycles CY subsequent to the multiple reference cycles RCY. Step STAe is performed at least partially in parallel with step STAd. In step STAe, the source radio-frequency power RF is provided from an RF power supply (e.g., the RF power supply 31) to generate plasma in the chamber in each of the multiple waveform cycles CY The multiple frequencies in the initial frequency group, or in other words, the multiple specific frequencies, are set as the source frequencies of the source radio-frequency power RF in the multiple phase periods SP in at least one or all of the multiple waveform cycles CY.

With the method MTA, the multiple specific frequencies, or in other words, the multiple frequencies in the initial frequency group, may be set in the respective multiple phase periods SP in the first waveform cycle CY(1) of the multiple waveform cycles CY. In the multiple waveform cycles CY, the feedback described above may be performed.

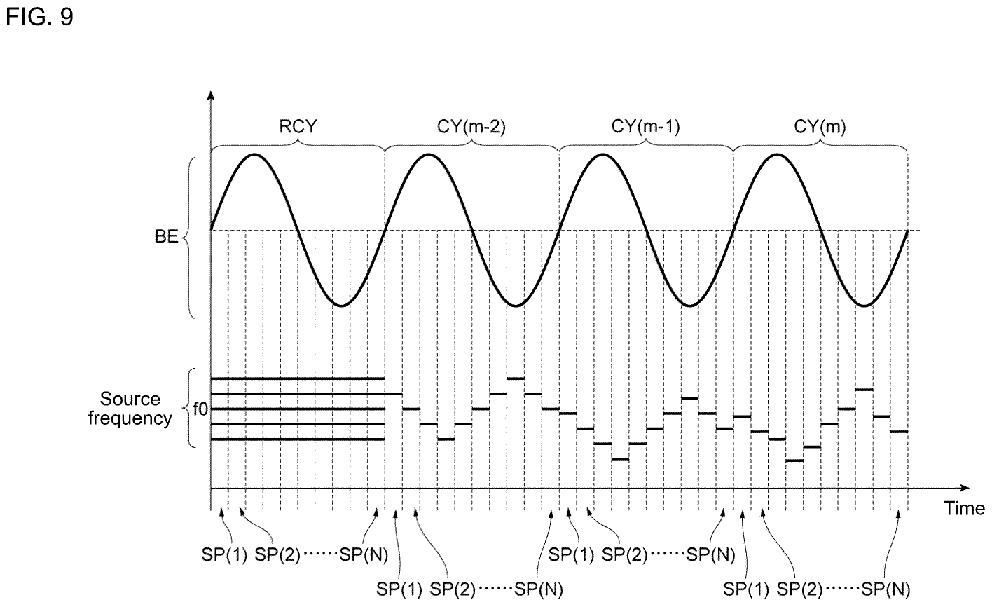

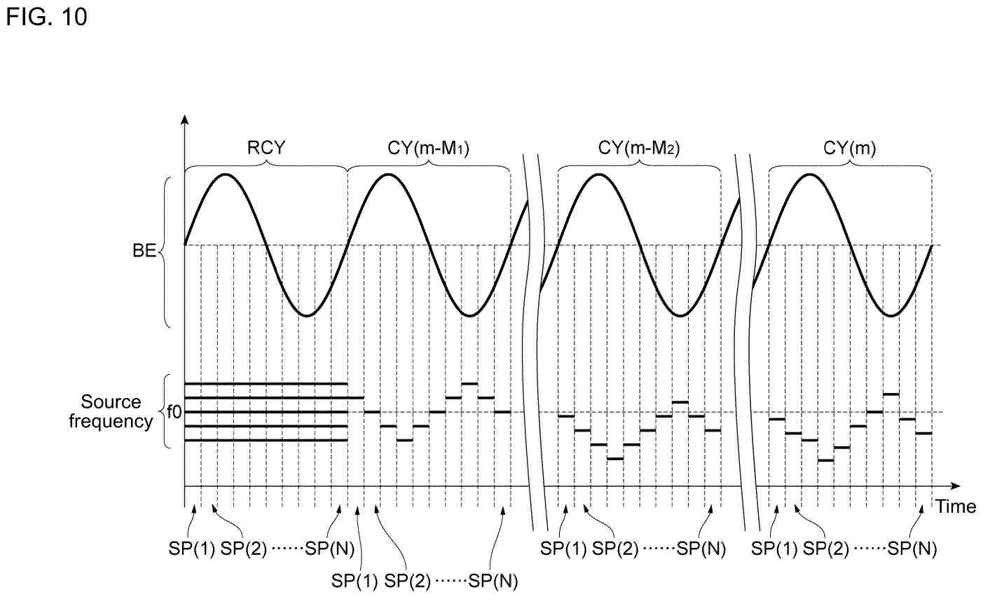

FIGS. 9 and 10 will now be referred to FIGS. 9 and 10 are each another example timing chart of bias energy and the source frequency of source RF power. In one embodiment, the controller 30c controls the RF power supply 31 to generate the source radio-frequency power RF with multiple frequency components to generate plasma in the chamber in a reference cycle RCY of the bias energy BE. The reference cycle RCY is a waveform cycle preceding the multiple waveform cycles CY. In one embodiment, the reference cycle RCY is the waveform cycle of the bias energy BE provided to the bias electrode in a preliminary period before the above process period to determine the initial frequency group. In the preliminary period, the initial frequency group may be determined under the condition for the process to be performed in the process period. The reference cycle RCY is defined by the above bias frequency and has the same time length as each of the multiple waveform cycles CY. In other words, the reference cycle RCY is the waveform cycle of the bias energy BE and has a time length being the inverse of the bias frequency. The bias energy BE is provided to the bias electrode in the reference cycle RCY, as in each of the multiple waveform cycles CY. In the multiple waveform cycles CY, the substrate W may be placed on the substrate support 11 while plasma is being generated. In the reference cycle RCY, the substrate W may or may not be placed on the substrate support 11.

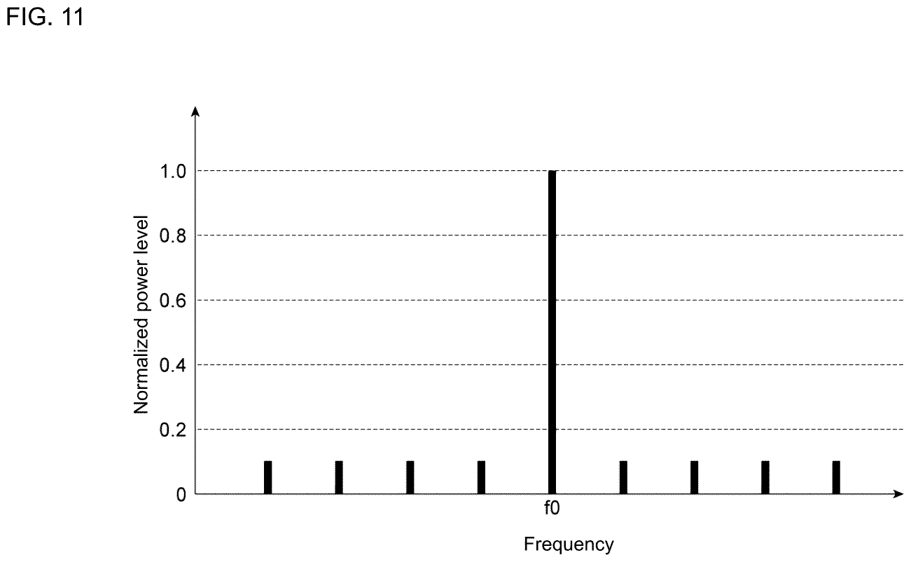

FIG. 11 is a graph of an example power spectrum of source RF power. In FIG. 11, the horizontal axis shows the frequency, and the vertical axis shows the normalized power level of the multiple frequency components of source RF power. The source radio-frequency power RF for the reference cycle RCY includes a frequency component having a reference frequency fit and multiple frequency components each having a frequency different from the reference frequency f0. Each of the multiple frequency components may have a lower power level than the frequency component having the reference frequency f0. In one embodiment, each of the multiple frequency components may have a power level lower than or equal to one tenth of the power level of the frequency component having the reference frequency f0. In one embodiment, the reference frequency f0 may be the central frequency of the multiple frequencies of the respective multiple frequency components. The multiple frequencies of the respective multiple frequency components may be at regular or irregular intervals. In one 75 embodiment, the multi pie frequencies of the respective multiple frequency components may be at intervals smaller than the frequency shift amount (described later).

As shown in FIGS. 9 and 10, the reference cycle RCY and the multiple waveform cycles CY each include the multiple phase periods SP. In other words, the reference cycle RCY and the multiple waveform cycles CY are each divided into N phase periods SP(1) to SP(N), where N is an integer greater than or equal to 2. The reference cycle RCY and the multiple waveform cycles CY may be each equally divided into the N phase periods SP(1) to SP(N). A phase period SP(n) herein refers to the n-th phase period of the phase periods SP(1) to SP(N) in the reference cycle RCY and in each of the multiple waveform cycles CY.

The controller 30c determines multiple ratios of the power levels Pr of the reflected waves of the multiple frequency components to the power levels Pf of the traveling waves of the multiple frequency components in each of the multiple phase periods SP(1) to SP(N) in the reference cycle RCY. The controller 30c can determine the power levels Pr of the reflected wave of the respective multiple frequency components by spectral analysis on the reflected waves output by the sensor 31s. In one example, the spectral analysis may be performed by a fast Fourier transform or a discrete Fourier transform. The controller 30c determines the lowest ratio of the multiple ratios. The controller 30c identifies a specific frequency being the frequency of the frequency component of the multiple frequency components corresponding to the lowest ratio in each of the multiple phase periods SP. The controller 30c thus determines multiple specific frequencies of the source radio-frequency power RF for the respective multiple phase periods SP. The multiple specific frequencies for the respective phase periods SP(1) to SP(N) are stored into the storage in the plasma processing apparatus 1 as the multiple frequencies in the initial frequency group.

The plasma processing apparatus 1 uses the source radio-frequency power RF with multiple frequency components in the reference cycle RCY, and can thus determine, in a short time, multiple specific frequencies of the source radio-frequency power RF for reducing the degrees of reflection in the multiple phase periods SP, This can reduce the degree of reflection of the source radio-frequency power RF in each of the multiple waveform cycles in Which the bias energy BE is provided to the bias electrode.

In one embodiment, the multiple specific frequencies, or in other words, the multiple frequencies in the initial frequency group, may be set in the respective multiple phase periods SP in the first waveform cycle CY(1) of the multiple waveform cycles CY In the multiple waveform cycles CY, the feedback described above may be performed.

In this case, the plasma processing apparatus 1 can finely adjust, using the above frequency shift, the source frequency for each of the multiple phase periods SP in each of the multiple waveform cycles CY to reduce the degree of reflection,

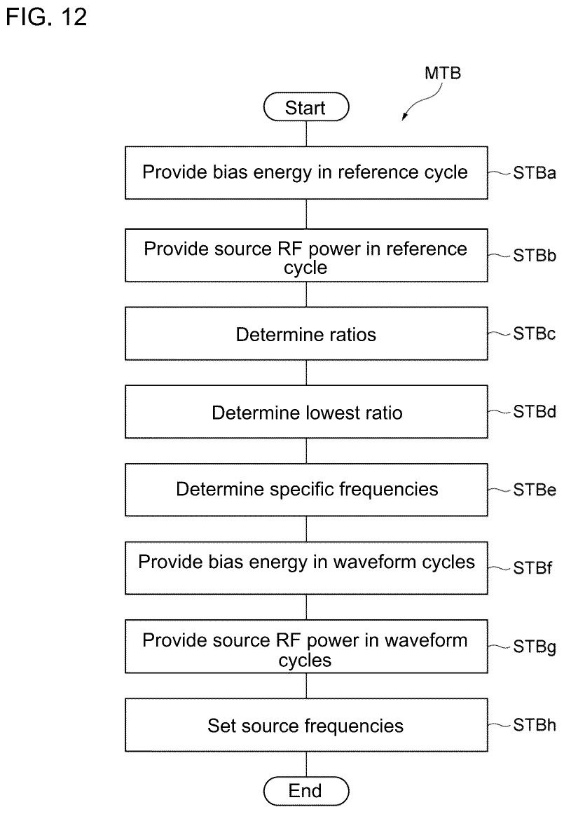

A method for determining the source frequency of source RF power according to one exemplary embodiment will now be described with reference to FIG. 12. FIG. 12 is a flowchart of a method for determining the source frequency of source RF power according to another exemplary embodiment. A method MTB in FIG. 12 starts from step STBa or step STBb.

In step STBa, the bias energy BE is provided to the bias electrode in the reference cycle RCY. Step STBb is performed in parallel with step STBa. In step STBb, the source radio-frequency power RF is provided from an RF power supply (e.g., the RF power supply 31) to generate plasma in the chamber in the reference cycle RCY The source radio-frequency power RF provided in the reference cycle RCY includes multiple frequency components as described above.

In step STBc, the above multiple ratios are determined. As described above, the multiple ratios are the ratios of the power levels of the reflected waves of the multiple frequency components to the power levels of the traveling waves of the multiple frequency components in each of the multiple phase periods SP in the reference cycle RCY In step STBd, the lowest ratio of the multiple ratios is determined. The lowest ratio is determined for each of the multiple phase periods SP in the reference cycle RCY.

In step STBe, multiple specific frequencies of the source radio-frequency power RF are determined for the respective phase periods SP(1) to SP(N), as described above. To determine the multiple specific frequencies, the frequency of the frequency component of the multiple frequency components corresponding to the lowest ratio is identified in each of the multiple phase periods SP(1) to SP(N).

The method MTB may further include step STBf, step STBg, and step STBh. In step STBf, bias energy is provided to the bias electrode in each of the multiple waveform cycles CY subsequent to the reference cycle RCY. Step STBg is performed in parallel with step STBf. In step STBg, the source radio-frequency power RF is provided from an RF power supply (e.g., the RF power supply 31) to generate plasma in the chamber. In step STBg, the multiple frequencies in the initial frequency group, or in other words, the multiple specific frequencies, are set as the source frequencies of the source radio-frequency power RF for the respective multiple phase periods SP in at least one of the multiple waveform cycles CY. The at least one waveform cycle may be the first waveform cycle CY(1) of the multiple waveform cycles CY.

In step STBh, the source frequency is set in each of the multiple phase periods SP in waveform cycles subsequent to the at least one waveform cycle of the multiple waveform cycles CY. In other words, in step STBh, the feedback described above is performed.

The plasma processing apparatus 1 may create the above initial frequency group under the condition for each of multiple processes to create multiple initial frequency groups for the respective multiple processes. The plasma processing apparatus 1 may store the multiple initial frequency groups into its storage in a manner associated with pieces of identification information about the respective multiple processes. The plasma processing apparatus 1 may select, from the multiple initial frequency groups, the initial frequency group corresponding to the process to be performed, and may set the selected initial frequency group as described above.

In one embodiment, the plasma processing apparatus 1 may use, selectively from predefined multiple optimal settings, the optimal setting corresponding, to the process of the multiple processes to be performed. Each of the multiple optimal settings includes the optimal matcher setting for the matcher 31m and the initial frequency group. The multiple optimal settings may be stored in the storage in the plasma processing apparatus 1 in a manner associated with pieces of identification information about the respective multiple processes.

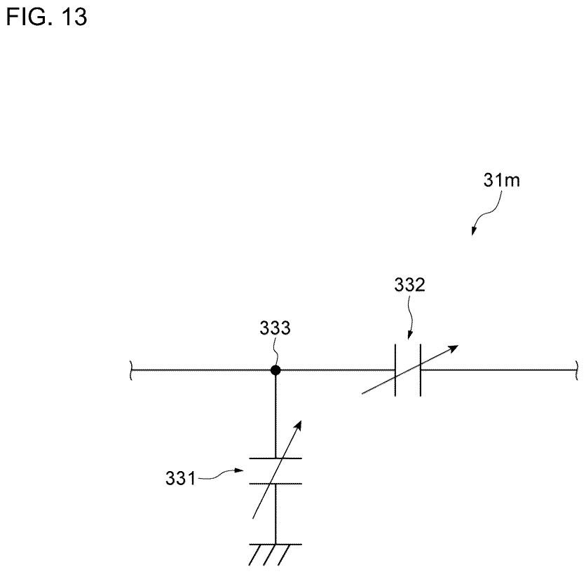

FIG. 13 is a diagram of an example matcher. As shown in FIG. 13, the matcher 31m may include a first variable capacitor 331 and a second variable capacitor 332. The first variable capacitor 331 is coupled between a node 333 and the ground. The node 333 is located on the feed line coupling the RF power supply 31 and the RF electrode. The source radio-frequency power RF is provided to the RF electrode through the feed line. The second variable capacitor 332 is coupled between the node 333 and the RF electrode. A capacitance C1 of the first variable capacitor 331 and a capacitance C2 of the second variable capacitor 332 may be controlled by, for example, the controller 2 or the controller 30c. The optimal setting for the matcher 31m includes a variable value of the first variable capacitor 331 and a variable value of the second variable capacitor 332. The variable value of the first variable capacitor 331 is the capacitance C1 or the position that determines the capacitance C1. The variable value of the second variable capacitor 332 is, for example, the capacitance C2 or the position that determines the capacitance C2.

In one embodiment, the matcher 31m uses, selectively from the predefined multiple optimal matcher settings, the optimal matcher setting corresponding to the process to be performed in the plasma processing apparatus 1 to set the variable value of the first variable capacitor 331 and the variable value of the second variable capacitor 332 in the first waveform cycle CY(1). The optimal matcher setting is included in the optimal setting selected as described above. In the multiple phase periods SP in the first waveform cycle CY(1), the RF power supply 31 may set, selectively from the multiple predefined initial frequency groups, the multiple frequencies included in the initial frequency group corresponding to the process to be performed in the plasma processing apparatus 1. The initial frequency group is included in the optimal setting selected as described above.

In one embodiment, the above process period may include an ignition period preceding or immediately preceding the multiple waveform cycles CY, In the ignition period, the bias energy BE is periodically provided to the bias electrode, and the source radio-frequency power RF having a fixed source frequency is provided to the RF electrode. The source frequency in the ignition period is predetermined as appropriate for plasma ignition. In the ignition period, the first variable capacitor 331 and the second variable capacitor 332 each have its variable value changed from the initial value to be closer to the optimal matcher setting.

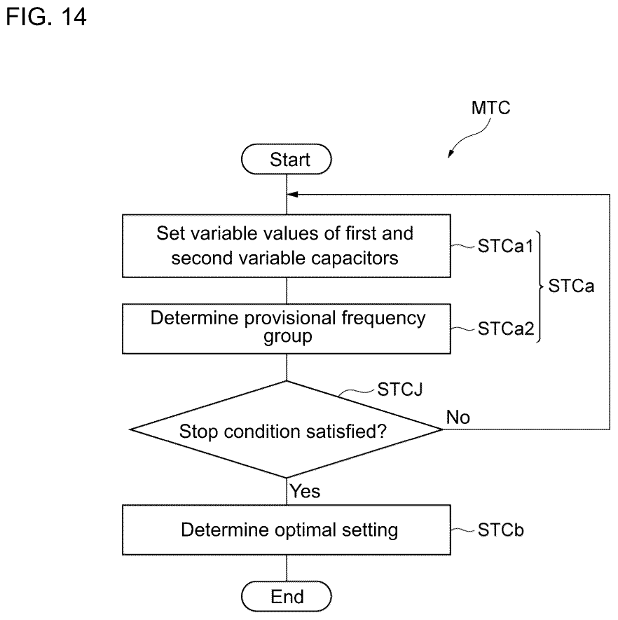

The determination of the optimal setting in some embodiments will now be described with reference to FIG. 14. FIG. 14 is a flowchart of a method for determining the optimal setting according to one exemplary embodiment. A method MTC in FIG. 14 is performed every time a new process recipe is registered with the storage in the plasma processing apparatus 1.

In step STCa with the method MTC, the controller 30c generates multiple provisional settings while sequentially switching the matcher setting for the first variable capacitor 331 and for the second variable capacitor 332 among multiple matcher settings under the condition for the process. Step STCa includes step STCa1 and step STCa2,

In step STCa1, the variable value of each of the first variable capacitor 331 and the second variable capacitor 332 is set to a value included in an unused matcher setting of the multiple matcher settings. With the method MTC, the variable value of each of the first variable capacitor 331 and the second variable capacitor 332 is set discretely in the multiple matcher settings. With the method MTC, the variable value of each of the first variable capacitor 331 and the second variable capacitor 332 may have the discreteness level specified in the process recipe.

In step STCa2, a provisional frequency group including multiple provisional frequencies is determined. In one embodiment, the controller 30c may generate a provisional frequency group including, as the multiple provisional frequencies, the multiple specific frequencies obtained through step STAa to step STAc with the method MTA. In some embodiments, in step STCa2, the controller 30c may generate a provisional frequency group including, as the multiple provisional frequencies, the multiple specific frequencies obtained through step STBa to step STBe with the method MTB. The controller 30c generates a provisional setting including the generated provisional frequency group and including the current matcher setting.

The controller 30c determines whether a stop condition is satisfied in step STCJ. The stop condition is satisfied when the multiple matcher settings include no unused matcher setting. When the multiple matcher settings include an unused matcher setting, the controller 30c returns to step STCa1 and uses the unused matcher setting. The controller 30c then performs step STCa2.

When the stop condition is satisfied in step STCJ, multiple provisional settings are obtained. In step STCb, the controller 30c identifies, from the multiple provisional settings, the provisional setting minimizing the degree of reflection of the source radio-frequency power RF in a waveform cycle. The degree of reflection may be the average (e.g., the average of the power levels Pr of the reflected waves) in the waveform cycle. The controller 30c stores, into the storage in the plasma processing apparatus 1, the matcher setting and the provisional frequency group included in the identified provisional setting as the optimal matcher setting and the initial frequency group corresponding to the above process. In other words, the controller 30c stores, into the storage in the plasma processing apparatus 1, the matcher setting and the provisional frequency group included in the identified provisional setting as the optimal setting, and the optimal setting includes the optimal matcher setting and the initial frequency group corresponding to the above process.

Although the exemplary embodiments have been described above, the embodiments are not restrictive, and various additions, omissions, substitutions, and changes may be made. The components in the different embodiments may be combined to form another embodiment.

In other embodiments, the plasma processing apparatus may be an ICP plasma processing apparatus, an ECR plasma processing apparatus, an HWP plasma processing apparatus, or an SGP plasma processing apparatus, as described above. Any of the above plasma processing apparatuses uses the source radio-frequency power RE to generate plasma and adjusts the source frequencies of the source radio-frequency power RF for the multiple phase periods SP in the multiple waveform cycles CY, similarly to the plasma processing apparatus 1 described above.

The source frequency of the source radio-frequency power RE in the phase period SP(m, n) may be determined to be the frequency minimizing the degree of reflection based on two or more degrees of reflection (e.g., the power levels Pr) obtained by setting different source frequencies in the corresponding phase periods SP(n) in two or more waveform cycles CY preceding the waveform cycle CY(m). The frequency minimizing the degree of reflection may be determined with the method of least squares using the different frequencies and their corresponding degrees of reflection.

Other embodiments EA1 to EA8, EB1 to EB4, and EC1 to EC13 of the present disclosure will now be described.

### EA1

A plasma processing apparatus, comprising:

a Chamber;

a substrate support located in the chamber and including a bias electrode;

a radio-frequency power supply configured to generate radio-frequency power to generate plasma in the chamber;

a bias power supply configured to provide bias energy to the bias electrode in each of a plurality of cycles defined by a bias frequency;

a sensor configured to output a reflected wave of the radio-frequency power returning from a load coupled to the radio-frequency power supply; and

a controller configured to control the radio-frequency power supply,

wherein the controller sets a frequency of the radio-frequency power in each of a plurality of phase periods in each of the plurality of cycles, and

adjusts the frequency of the radio-frequency power in an n-th phase period of the plurality of phase periods in an m-th cycle of the plurality of cycles based on a change in a power level of the reflected wave output from the sensor occurring when the frequency of the radio-frequency power is set differently in a corresponding phase period in each of two or more cycles of the plurality of cycles preceding the m-th cycle.

### EA2

The plasma processing apparatus according to embodiment EA1, wherein the two or more cycles include a first cycle and a second cycle subsequent to the first cycle, and in response to the power level of the reflected wave decreasing with the frequency of the radio-frequency power in the n-th phase period in the second cycle being set to a frequency resulting from a frequency shift in a first direction being one of a decrease or an increase from the frequency of the radio-frequency power in the n-th phase period in the first cycle, the controller sets the frequency of the radio-frequency power in the n-th phase period in the m-th cycle to a frequency resulting from the frequency shift in the first direction from the frequency of the radio-frequency power in the n-th phase period in the second cycle.

### EA3

The plasma processing apparatus according to embodiment EA2, wherein

in response to the power level of the reflected wave increasing with the frequency of the radio-frequency power in the n-th phase period in the m-th cycle being set to the frequency resulting from the frequency shift in the first direction from the frequency of the radio-frequency power in the n-th phase period in the second cycle, the controller sets the frequency of the radio-frequency power in the n-th phase period in a third cycle of the plurality of cycles subsequent to the m-th cycle to an intermediate frequency between the frequency of the radio-frequency power in the n-th phase period in the second cycle and the frequency of the radio-frequency power in the n-th phase period in the m-th cycle.

### EA4

The plasma processing apparatus according to embodiment EA3, wherein

in response to the power level of the reflected wave exceeding a threshold when the intermediate frequency is set in the n-th phase period in the third cycle, the controller sets the frequency of the radio-frequency power in the n-th phase period in a fourth cycle of the plurality of cycles subsequent to the third cycle to a frequency resulting from a frequency shift in a second direction being the other of the decrease or the increase from the intermediate frequency, and an amount of the frequency shift in the second direction has a greater absolute value than an amount of the frequency shift in the first direction.

### EA5

The plasma processing apparatus according to embodiment EA2, wherein

an amount of the frequency shift in the first direction has a greater absolute value for the frequency of the radio-frequency power in the n-th phase period in the m-th cycle than for the frequency of the radio-frequency power in the n-th phase period in the second cycle.

### EA6

The plasma processing apparatus according to embodiment EA1, wherein

the two or more cycles include a first cycle and a second cycle subsequent to the first cycle, and

in response to the power level of the reflected wave increasing with the frequency of the radio-frequency power in the n-th phase period in the second cycle being set to a frequency resulting from a frequency shift in a first direction being one of a decrease or an increase from the frequency of the radio-frequency power in the n-th phase period in the first cycle, the controller sets the frequency of the radio-frequency power in the n-th phase period in the m-th cycle to a frequency resulting from a frequency shift in a second direction being the other of the decrease or the increase from the frequency of the radio-frequency power in the n-th phase period in the second cycle.

### EA7

The plasma processing apparatus according to any one of embodiments EA1 to EA6, wherein

the bias energy is radio-frequency power having the bias frequency, or includes a pulse of a voltage provided to the bias electrode in each of the plurality of cycles.

### EA8

A method for controlling a frequency of radio-frequency power, the method comprising:

providing bias energy to a bias electrode in each of a plurality of cycles defined by a bias frequency, the bias electrode being located on a substrate support in a chamber in a plasma processing apparatus;

providing the radio-frequency power from a radio-frequency power supply to generate plasma in the chamber; and

setting a frequency of the radio-frequency power in each of a plurality of phase periods in each of the plurality of cycles for the radio-frequency power,

wherein the frequency of the radio-frequency power in an n-th phase period of the plurality of phase periods in an m-th cycle of the plurality of cycles is adjusted based on a change in a power level of a reflected wave of the radio-frequency power occurring when the frequency of the radio-frequency power is set differently in a corresponding phase period in each of two or more cycles of the plurality of cycles preceding the m-th cycle.

### EB1

A plasma processing apparatus, comprising:

a chamber;

a substrate support located in the chamber and including a bias electrode;

a radio-frequency power supply configured to generate radio-frequency power to generate plasma in the chamber;

a bias power supply configured to provide bias energy to the bias electrode in each of a plurality of cycles defined by a bias frequency;

a sensor configured to output a reflected wave of the radio-frequency power returning from a load coupled to the radio-frequency power supply; and

a controller configured to control the bias power supply and the radio-frequency power supply,

wherein the controller controls the bias power supply to provide the bias energy to the bias electrode in each of a plurality of reference cycles including a plurality of phase periods and being defined by the bias frequency,

controls the radio-frequency power supply to set a plurality of frequencies different from each other as frequencies of the radio-frequency power in identical phase periods in the plurality of reference cycles, and

selects, from the plurality of frequencies, a specific frequency minimizing a power level of the reflected wave output from the sensor in each of the plurality of phase periods to determine a plurality of specific frequencies of the radio-frequency power for the respective plurality of phase periods.

### EB2

The plasma processing apparatus according to embodiment EB1, wherein

the controller controls the radio-frequency power supply to set the plurality of specific frequencies as frequencies of the radio-frequency power in the respective plurality of phase periods in at least one cycle of the plurality of cycles subsequent to the plurality of reference cycles.

### EB3

The plasma processing apparatus according to embodiment EB2, wherein

in the plurality of cycles, plasma processing is performed on a substrate placed on the substrate support.

### EB4

A method for determining a frequency of radio-frequency power, the method comprising:

providing bias energy to a bias electrode in each of a plurality of reference cycles, each of the plurality of reference cycles including a plurality of phase periods and being defined by a.

bias frequency, the bias electrode being located on a substrate support in a chamber in a plasma processing apparatus;

providing the radio-frequency power from a radio-frequency power supply in the plurality of reference cycles to generate plasma in the chamber, with a plurality of frequencies different from each other being set as frequencies of the radio-frequency power in identical phase periods in the plurality of reference cycles; and selecting, from the plurality of frequencies, a specific frequency minimizing a power level of a reflected wave of the radio-frequency power in each of the plurality of phase periods to determine a plurality of specific frequencies of the radio-frequency power for the respective plurality of phase periods.

### EC1

A plasma processing apparatus, comprising:

a chamber;

a substrate support located in the chamber and including a bias electrode;

a radio-frequency power supply configured to generate radio-frequency power to generate plasma in the chamber;

a bias power supply configured to provide bias energy to the bias electrode in each of a plurality of cycles defined by a bias frequency;

a sensor configured to output a reflected wave of the radio-frequency power returning from a load coupled to the radio-frequency power supply; and

a controller configured to control the radio-frequency power supply,

wherein the controller controls the radio-frequency power supply to generate radio-frequency power having a plurality of frequency components to generate plasma in the chamber in a reference cycle defined by the bias frequency and being a cycle in which the bias energy is provided to the bias electrode,

determines a lowest ratio of a plurality of ratios of power levels of reflected waves of the plurality of frequency components to power levels of traveling waves of the plurality of frequency components in each of a plurality of phase periods in the reference cycle, and

identifies a frequency of a frequency component of the plurality of frequency components corresponding to the lowest ratio in each of the plurality of phase periods to determine a plurality of specific frequencies of the radio-frequency power for the respective plurality of phase periods.

### EC2

The plasma processing apparatus according to embodiment EC1, wherein

the plurality of frequency components include a component having a reference frequency and a plurality of components each having a frequency different from the reference frequency, and

each of the plurality of components has a lower power level than the component having the reference frequency.

### EC3

The plasma processing apparatus according to embodiment EC2, wherein

each of the plurality of components has a power level lower than or equal to one tenth of a power level of the component having the reference frequency.

### EC4

The plasma processing apparatus according to embodiment EC2 or embodiment EC3, wherein

the reference frequency is a central frequency of a plurality of frequencies of the respective plurality of frequency components.

### EC5

The plasma processing apparatus according to any one of embodiments EC1 to EC4, wherein

the controller controls the radio-frequency power supply to set the plurality of specific frequencies as frequencies of the radio-frequency power in the respective plurality of phase periods in at least one cycle of the plurality of cycles.

### EC6

The plasma processing apparatus according to embodiment EC1, wherein

the controller adjusts the frequency of the radio-frequency power in an n-th phase period of the plurality of phase periods in an m-th cycle of the plurality of cycles subsequent to the at least one cycle based on a change in a power level of the reflected wave output from the sensor occurring when the frequency of the radio-frequency power is set differently in a corresponding phase period in each of two or more cycles of the plurality of cycles preceding the m-th cycle.

### EC7

The plasma processing apparatus according to embodiment EC6, wherein

the two or more cycles include a first cycle and a second cycle subsequent to the first cycle, and

in response to the power level of the reflected wave decreasing with the frequency of the radio-frequency power in the n-th phase period in the second cycle being set to a frequency resulting from a frequency shift in a first direction being one of a decrease or an increase from the frequency of the radio-frequency power in the n-th phase period in the first cycle, the controller sets the frequency of the radio-frequency power in the n-th phase period in the m-th cycle to a frequency resulting from the frequency shift in the first direction from the frequency of the radio-frequency power in the n-th phase period in the second cycle.

### EC8

The plasma processing apparatus according to embodiment EC7, wherein

in response to the power level of the reflected wave increasing with the frequency of the radio-frequency power in the n-th phase period in the m-th cycle being set to the frequency resulting from the frequency shift in the first direction from the frequency of the radio-frequency power in the n-th phase period in the second cycle, the controller sets the frequency of the radio-frequency power in the n-th phase period in a third cycle of the plurality of cycles subsequent to the m-th cycle to an intermediate frequency between the frequency of the radio-frequency power in the n-th phase period in the second cycle and the frequency of the radio-frequency power in the n-th phase period in the m-th cycle.

### EC9

The plasma processing apparatus according to embodiment EC8, wherein

in response to the power level of the reflected wave exceeding a threshold when the intermediate frequency is set in the n-th phase period in the third cycle, the controller sets the frequency of the radio-frequency power in the n-th phase period in a fourth cycle of the plurality of cycles subsequent to the third cycle to a frequency resulting from a frequency shift in a second direction being the other of the decrease or the increase from the intermediate frequency, and an amount of the frequency shift in the second direction has a greater absolute value than an amount of the frequency shift in the first direction.

### EC10

The plasma processing apparatus according to embodiment EC7, wherein

an amount of the frequency shift in the first direction has a greater absolute value for the frequency of the radio-frequency power in the n-th phase period in the m-th cycle than for the frequency of the radio-frequency power in the n-th phase period in the second cycle.

### EC11

The plasma processing apparatus according to embodiment EC6, wherein

the two or more cycles include a first cycle and a second cycle subsequent to the first cycle, and

in response to the power level of the reflected wave increasing with the frequency of the radio-frequency power in the n-th phase period in the second cycle being set to a frequency resulting from a frequency shift in a first direction being one of a decrease or an increase from the frequency of the radio-frequency power in the n-th phase period in the first cycle, the controller sets the frequency of the radio-frequency power in the n-th phase period in the m-th cycle to a frequency resulting from a frequency shift in a second direction being the other of the decrease or the increase from the frequency of the radio-frequency power in the n-th phase period in the second cycle.

### EC12

The plasma processing apparatus according to any one of embodiments EC1 to EC11, wherein

the bias energy is radio-frequency power having the bias frequency, or includes a pulse of a negative voltage provided to the bias electrode in each of the plurality of cycles.

### EC13

A method for determining a frequency of radio-frequency power, the method comprising:

providing bias energy to a bias electrode in a reference cycle defined by a bias frequency, the bias electrode being located on a substrate support in a chamber in a plasma processing apparatus;

providing the radio-frequency power from a radio-frequency power supply in the reference cycle to generate plasma in the chamber, the radio-frequency power having a plurality of frequency components;

determining a plurality of ratios of power levels of reflected waves of the plurality of frequency components to power levels of traveling waves of the plurality of frequency components in each of a plurality of phase periods in the reference cycle;

determining a lowest ratio of the plurality of ratios; and

identifying a frequency of a frequency component of the plurality of frequency components corresponding to the lowest ratio in each of the plurality of phase periods to determine a plurality of specific frequencies of the radio-frequency power for the respective plurality of phase periods.

The exemplary embodiments according to the present disclosure have been described by way of example, and various changes may be made without departing from the scope and spirit of the present disclosure. The exemplary embodiments disclosed above are thus not restrictive, and the true scope and spirit of the present disclosure are defined by the appended claims.

### REFERENCE SIGNS LIST

1 Plasma processing apparatus
10 Plasma processing chamber
11 Substrate support
31 RF power supply
32 Bias power supply
31s Sensor
30c Controller

1. A plasma processing apparatus, comprising:
a chamber;
a substrate support located in the chamber and including a bias electrode;
a radio-frequency power supply configured to generate source radio-frequency power to generate plasma in the chamber; and
a bias power supply configured to periodically provide bias energy having a waveform cycle to the bias electrode,
wherein the radio-frequency power supply is configured to set a source frequency of the source radio-frequency power in each of a plurality of phase periods in each of a plurality of waveform cycles of the bias energy, and
provide feedback to adjust the source frequency in an n-th phase period of the plurality of phase periods in an m-th waveform cycle of the plurality of waveform cycles based on a change in a degree of reflection of the source radio-frequency power that occurs under a condition the source frequency is set differently in the n-th phase period in each of two or more waveform cycles of the plurality of waveform cycles preceding the m-th waveform cycle.

2. The plasma processing apparatus according to claim 1, wherein
the two or more waveform cycles include an (m−M₁)th waveform cycle and an (m−M₂)th waveform cycle, and M₁ and M₂ are natural ambers satisfying M₁>M₂, and
the radio-frequency power supply employs the feedback to set, in response to the degree of reflection decreasing with the source frequency in the n-th phase period in the (m−M₂)th waveform cycle being set to a frequency resulting from a frequency shift in a first direction being one of a decrease or an increase from the source frequency in the n-th phase period in the (m−M₁)th waveform cycle, the source frequency in the n-th phase period in the m-th waveform cycle to a frequency resulting from the frequency shift in the first direction from the source frequency in the n-th phase period in the (m−M₂)th waveform cycle.

3. The plasma processing apparatus according to claim 2, wherein
the radio-frequency power supply employs the feedback to further set, in response to the degree of reflection increasing with the source frequency in the n-th phase period in the m-th waveform cycle being set to the frequency resulting from the frequency shift in the first direction from the source frequency in the n-th phase period in the (m−M₂)th waveform cycle, the source frequency in the n-th phase period in an (m+M₃)th waveform cycle of the plurality of waveform cycles to an intermediate frequency between the source frequency in the n-th phase period in the (m−M₂)th waveform cycle and the source frequency in the n-th phase period in the m-th waveform cycle, and M₃ is a natural number.

4. The plasma processing apparatus according to claim 3, wherein
the radio-frequency power supply employs the feedback to further set, in response to the degree of reflection exceeding a threshold under a condition the intermediate frequency is set in the n-th phase period in the (m M₃)th waveform cycle, the source frequency in the n-th phase period in an (m+M₄)th waveform cycle of the plurality of waveform cycles to a frequency resulting from a frequency shift in a second direction being the other of the decrease or the increase from the intermediate frequency, an amount of the frequency shift in the second direction has a greater absolute value than an amount of the frequency shift in the first direction, and M₄ is a natural number satisfying M₄>M₃.

5. The plasma processing apparatus according to claim 2, wherein
an amount of the frequency shift in the first direction has a greater absolute value for the source frequency in the n-th phase period in the m-th waveform cycle than for the source frequency in the n-th phase period in the (m−2)th waveform cycle.

6. The plasma processing apparatus according to claim 1, wherein
the two or more waveform cycles include an (m M₁)th waveform cycle and an (m−M₂)th waveform cycle, and M₁ and M₂ are natural numbers satisfying M₁>M₂, and
the radio-frequency power supply employs the feedback to further set, in response to the degree of reflection increasing with the source frequency in the n-th phase period in the (m−M₂)th waveform cycle being set to a frequency resulting from a frequency shift in a first direction being one of a decrease or an increase from the source frequency in the n-th phase period in the (m−M₁)th waveform cycle, the source frequency in the n-th phase period in the m-th waveform cycle to a frequency resulting from a frequency shift in a second direction being the other of the decrease or the increase from the source frequency in the n-th phase period in the (m−M₂)th waveform cycle.

7. The plasma processing apparatus according to claim 1, wherein
the bias energy is bias radio-frequency power having a bias frequency being an inverse of a length of time of the waveform cycle or includes a pulse of a voltage provided to the bias electrode in each of the plurality of waveform cycles, and each of the plurality of waveform cycles has a time length being the inverse of the bias frequency.

8. The plasma processing apparatus according to claim 2, wherein
the bias energy is bias radio-frequency power having a bias frequency being an inverse of a length of time of the waveform cycle or includes a pulse of a voltage provided to the bias electrode in each of the plurality of waveform cycles, and each of the plurality of waveform cycles has a time length being the inverse of the bias frequency.

9. The plasma processing apparatus according to claim 1, wherein
the radio-frequency power supply is configured to set, in the plurality of phase periods in a first waveform cycle of the plurality of waveform cycles, a plurality of frequencies included in a predefined initial frequency group.

10. The plasma processing apparatus according to claim 2, wherein
the radio-frequency power supply is configured to set, in the plurality of phase periods in a first waveform cycle of the plurality of waveform cycles, a plurality of frequencies included in a predefined initial frequency group.

11. The plasma processing apparatus according to claim 9, further comprising:
a controller configured to set a plurality of frequencies different from each other as source frequencies in identical phase periods in a plurality of reference cycles each being the waveform cycle,
select, from the plurality of frequencies, a specific frequency minimizing the degree of reflection in each of the plurality of phase periods to determine a plurality of specific frequencies for the respective plurality of phase periods, and
store the plurality of specific frequencies into a storage in the plasma processing apparatus as the plurality of frequencies in the initial frequency group.

12. The plasma processing apparatus according to claim 10, further comprising:
a controller configured to set a plurality of frequencies different from each other as source frequencies in identical phase periods in a plurality of reference cycles each being the waveform cycle,
select, from the plurality of frequencies, a specific frequency minimizing the degree of reflection in each of the plurality of phase periods to determine a plurality of specific frequencies for the respective plurality of phase periods, and
store the plurality of specific frequencies into a storage in the plasma processing apparatus as the plurality of frequencies in the initial frequency group.

13. The plasma processing apparatus according to claim 9, further comprising:
a controller configured to cause the radio-frequency power supply to generate source radio-frequency power having a plurality of frequency components to generate plasma in the chamber in a reference cycle being the waveform cycle,
determine a lowest ratio of a plurality of ratios of power levels of reflected waves of the plurality of frequency components to power levels of traveling waves of the plurality of frequency components in each of the plurality of phase periods in the reference cycle,
identify a frequency of a frequency component of the plurality of frequency components corresponding to the lowest ratio in each of the plurality of phase periods to determine a plurality of specific frequencies for the respective plurality of phase periods, and
store the plurality of specific frequencies into a storage in the plasma processing apparatus as the plurality of frequencies in the initial frequency group.

14. The plasma processing apparatus according to claim 1, further comprising:
a matching circuitry including
a first variable capacitor coupled between a ground and a node on a feed line coupling the radio-frequency power supply and a radio-frequency electrode to receive the source radio-frequency power, and
a second variable capacitor coupled between the node and the radio-frequency electrode,
wherein in a first waveform cycle of the plurality of waveform cycles, the matching circuitry is configured to use, selectively from a plurality of predefined optimal matching circuitry settings for the first variable capacitor and for the second variable capacitor, an optimal matching circuitry setting corresponding to a process to be performed in the plasma processing apparatus, and
in the plurality of phase periods in the first waveform cycle, the radio-frequency power supply sets, selectively from a plurality of predefined initial frequency groups, a plurality of frequencies included in an initial frequency group corresponding to the process to be performed in the plasma processing apparatus.

15. The plasma processing apparatus according to claim 2, further comprising:
a matching circuitry including
a first variable capacitor coupled between a ground and a node on a feed line coupling the radio-frequency power supply and a radio-frequency electrode to receive the source radio-frequency power, and
a second variable capacitor coupled between the node and the radio-frequency electrode,
wherein in a first waveform cycle of the plurality of waveform cycles, the matching circuitry is configured to use, selectively from a plurality of predefined optimal matching circuitry settings for the first variable capacitor and for the second variable capacitor, an optimal matching circuitry setting corresponding to a process to be performed in the plasma processing apparatus, and
in the plurality of phase periods in the first waveform cycle, the radio-frequency power supply sets, selectively from a plurality of predefined initial frequency groups, a plurality of frequencies included in an initial frequency group corresponding to the process to be performed in the plasma processing apparatus.

16. The plasma processing apparatus according to claim 14, further comprising:
a controller configured to set, while sequentially switching a setting for the matching circuitry for the first variable capacitor and for the second variable capacitor among a plurality of settings under a condition for the process, a plurality of frequencies different from each other as source frequencies in identical phase periods in a plurality of reference cycles each being the waveform cycle, and select, from the plurality of frequencies, a provisional frequency minimizing the degree of reflection in each of the plurality of phase periods,
the controller being configured to generate a plurality of provisional settings each including a provisional frequency group and a corresponding setting of the plurality of settings, the provisional frequency group including a plurality of provisional frequencies for the respective plurality of phase periods,
the controller being configured to store, into a storage in the plasma processing apparatus, the setting and the provisional frequency group included in a provisional setting of the plurality of provisional settings minimizing the degree of reflection, the setting and the provisional frequency group being stored as the optimal matching circuitry setting and the initial frequency group corresponding to the process.

17. The plasma processing apparatus according to claim 14, further comprising:
a controller configured to cause, while sequentially switching a setting for the matching circuitry for the first variable capacitor and for the second variable capacitor among a plurality of settings under a condition for the process, the radio-frequency power supply to generate source radio-frequency power having a plurality of frequency components to generate plasma in the chamber in a reference cycle being the waveform cycle, determine a lowest ratio of a plurality of ratios of power levels of reflected waves of the plurality of frequency components to power levels of traveling waves of the plurality of frequency components in each of the plurality of phase periods in the reference cycle, and identify a frequency of a frequency component of the plurality of frequency components corresponding to the lowest ratio in each of the plurality of phase periods to determine a plurality of provisional frequencies for the respective plurality of phase periods,
the controller being configured to generate a plurality of provisional settings each including a provisional frequency group and a corresponding setting of the plurality of settings, the provisional frequency group including a plurality of provisional frequencies for the respective plurality of phase periods,
the controller being configured to store, into a storage in the plasma processing apparatus, the setting and the provisional frequency group included in a provisional setting of the plurality of provisional settings minimizing the degree of reflection, the setting and the provisional frequency group being stored as the optimal snatching circuitry setting and the initial frequency group corresponding to the process.

18. A method for controlling a source frequency of source radio-frequency power, the method comprising:
providing bias energy having a waveform cycle to a bias electrode periodically, the bias electrode being located on a substrate support in a chamber in a plasma processing apparatus;
providing the source radio-frequency power from a radio-frequency power supply to generate plasma in the chamber; and
setting a source frequency of the source radio-frequency power in each of a plurality of phase periods in each of a plurality of waveform cycles of the bias energy,
wherein the source frequency in an n-th phase period of the plurality of phase periods in an m-th waveform cycle of the plurality of waveform cycles is adjusted based on a change in a degree of reflection of the source radio-frequency power that occurs under a condition the source frequency is set differently in the n-th phase period in each of t or more waveform cycles of the plurality of waveform cycles preceding the m-th waveform cycle.
